(19) United States
(12) Patent Application Publication
(10) Pub. No.: US 2008/0105904 A1
(43) Pub. Date: May 8, 2008

(54) Method for variability constraints in design of integrated circuits especially digital circuits which includes timing closure upon placement and routing of digital circuit or network

(75) Inventors: Takashi Sumikawa, Osaka (JP); Kyoji Yamashita, Kyoto-shi (JP); Dai Motojima, Kyoto-shi (JP)

Correspondence Address: MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD., Osaka (JP)

(21) Appl. No.: 11/907,320

(22) Filed: Oct. 11, 2007

Related U.S. Application Data
(62) Division of application No. 11/080,456, filed on Mar. 16, 2005, now abandoned.

(30) Foreign Application Priority Data
Mar. 19, 2004 (JP) 2004-080618

(51) Int. Cl. H01L 29/00

(52) U.S. Cl. 257/202; 257/E29.112

(57) ABSTRACT

In a standard cell, dummy transistors have p-type and n-type dummy gate electrodes. The dummy transistors are in an OFF state all the time. The gate length of each of the dummy gate electrodes is extended over an end portion of a diffusion region toward the inside of the standard cell. Thus, the total surface area and the total perimeter of respective gate electrodes of all transistors provided in the standard cell are increased. As a result, for example, even though shapes of gate electrodes of transistors vary between the standard cell and each of other standard cells, transistor characteristics are substantially equal among the standard cells. Therefore, variations in delays of signals generated between the standard cells can be suppressed.

### CROSS REFERENCE TO RELATED APPLICATIONS

This non-provisional application claims priority under 35 U.S.C. § 119(a) on Patent Application No. 2004-080618 filed in Japan on Mar. 19, 2004, the entire contents of which are hereby incorporated by reference.

### BACKGROUND OF THE INVENTION

The present invention relates to a standard cell design method and a semiconductor integrated circuit fabricated by placement and routing using standard cells designed by the design method, and more preferably relates to a cell design method and a semiconductor integrated circuit which suppresses delay variations depending on a layout pattern.

In recent years, there has been rapid progress in reduction in size and improvement of functions for semiconductor integrated circuits. With the progress, the device length of semiconductor integrated circuits has been reduced for the purpose of improving performances of transistors.

In process steps for fabricating a semiconductor integrated circuit, fluctuation in fabrication conditions occurs and influences the shapes of circuit devices and physical conditions for thereof. Such influences appear as variations in electric characteristics among semiconductor devices. For example, when a circuit pattern of a reticle is exposed to light and transferred to a photo resist applied onto a semiconductor wafer by irradiating light to the reticle of a semiconductor integrated circuit using a photolithography device, a predetermined device length of a fabricated circuit device can not be achieved but the device length is reduced due to influences of diffracted light and the like, so that a fluctuation ratio for device lengths of the circuit devices becomes very large. Moreover, the variety of cell types has been increased and the shape of a cell varies depending on the type of the cell, so that a signal delay time of a circuit device largely depends on the shape of a cell. Thus, a maximum propagation delay coefficient of a signal becomes large. Therefore, it has been very difficult to provide high-performance semiconductor integrated circuits.

Conventionally, to cope with this problem, for example, in Japanese Laid-Open Publication No. 9-289251, as a technique for suppressing variations in delays of signals of a semiconductor integrated circuit, the following layout structure of a semiconductor integrated circuit is disclosed. Specifically, a plurality of transistors are formed using diffusion regions having MOSFET structure gate electrodes. As for the plurality of transistors, in active transistors to be used, the adjacent MOSFET gate electrodes of the active transistors are separated from each other by a certain distance, i.e., with a predetermined interval. Also, in part of the layout structure in which active transistors are not located adjacent to each other, a dummy transistor which is in an OFF state all the time is disposed. The dummy transistor and each of the active transistors located at the left and right side of the dummy transistor are disposed so that adjacent two MOFET gate electrodes are separated from each other by a certain distance, i.e., with a predetermined interval. By fabricating a standard cell in the above described manner, influences of diffracted light and the like when a circuit pattern of a reticle is exposed and transferred onto a photo resist which has been applied is made equal among the MOSFET gate electrodes of the dummy and active transistors, so that the respective device lengths of the MOSFET gate electrodes of the dummy and active transistors become substantially the same.

However, although the above described technique is effective in a layout structure for a known semiconductor integrated circuit, with further reduction in the size of semiconductor integrated circuits, it is desired to suppress furthermore variations in device shape depending on a layout pattern of a semiconductor integrated circuit so as to reduce variations in characteristics of the semiconductor integrated circuit.

### SUMMARY OF THE INVENTION

Then, the present inventors have conducted examinations of influences of diffracted light during light exposure and transcription for a standard cell to be designed. Specifically, because many different types of standard cells are designed, each of the cells has a different internal structure according to the type thereof. Thus, even if as in the known technique, an interval between adjacent MOSFET gate electrodes is set to be a certain distance for all of a plurality of transistors, influences of diffracted light during light exposure and transcription differ among the cells depending on the shape of each MOSFET gate electrode, the size of a diffusion region located around the cell, and the like. For example, as shown in a scanning electron microscope photo of FIG. 10 for an arbitrary standard cell, each of gate electrodes GA and diffusion regions OD actually has a shape with parts scraped off due to influences of diffracted light during exposure light and transcription. Therefore, it has been found that among the cells, variations in the shapes of MOSFET gate electrodes and diffusion regions depending on a layout pattern are caused. It has been also found that when a semiconductor integrated circuit is formed using many of such standard cells, fluctuation in characteristics of the semiconductor integrated circuit is increased.

It is therefore an object of the present invention to solve the above-described problems, to suppress variations in device shape among cells due to the dependency on layout pattern, and to reduce fluctuation in characteristics of a semiconductor integrated circuit.

To achieve the above-described object, according to the present invention, in a method for designing a standard cell, even if variations in device shape due to layout pattern dependency among cells are caused because of influences of diffracted light in light exposure and transcription, the area and shape of each of gate electrodes and diffusion regions in each cell are changed so that variations in device shape among cells become small.

Specifically, a method for designing a standard cell according to the present invention is a method for designing a standard cell including a plurality of transistors each of which includes a gate electrode and a diffusion region and is characterized in that of the plurality of transistors, a predetermined number of transistors are dummy transistors, each of the dummy transistors being in an OFF state at all the time, and a surface area of a gate electrode of each said dummy transistor is adjusted so that a difference in a total surface area of respective gate electrodes of all transistors belonging to the standard cell between the standard cell and each of other standard cells becomes small.

In one embodiment of the standard cell design method of the present invention, the method is characterized in that only a length of the gate electrode of each said dummy transistor is adjusted to control a surface area of the dummy transistor.

A method for designing a standard cell according to the present invention is a method for designing a standard cell including a plurality of transistors each of which includes a gate electrode and a diffusion region and is characterized in that of the plurality of transistors, a predetermined number of transistors are dummy transistors, each of the dummy transistors being in an OFF state at all the time, and a perimeter of a gate electrode of each said dummy transistor is adjusted so that a difference in a total perimeter of respective gate electrodes of all transistors belonging to the standard cell between the standard cell and each of other standard cells becomes small.

In one embodiment of the standard cell design method of the present invention, the method is characterized in that said dummy transistors include a p-type dummy transistor and an n-type dummy transistor disposed so as to be separated from each other by a predetermined distance and be opposed to each other, and respective gate electrodes of the p-type and n-type dummy transistors are extended and connected with each other.

In another embodiment of the standard cell design method of the present invention, the method is characterized in that when respective scales of the standard cell and other standard cells are different, the gate electrode of each said dummy transistor is adjusted according to the ratio between the scales of the standard cell and each of the other standard cells.

In still another embodiment of the standard cell design method of the present invention, the method is characterized in that said dummy transistors are located in two end portions of the standard cell.

A method for designing a standard cell according to the present invention is a method for designing a standard cell including a plurality of transistors each of which includes a gate electrode, a diffusion region and a substrate contact and is characterized in that said substrate contact provided in the standard cell is expanded toward the inside of the standard cell so that a difference in a total area of respective diffusion regions of all transistors belonging to the standard cell between the standard cell and each of other standard cells becomes small.

A method for designing a standard cell according to the present invention is a method for designing a standard cell including a plurality of transistors each of which includes a gate electrode, a diffusion region and a substrate contact and is characterized in that said substrate contact provided in the standard cell is expanded toward the inside of the standard cell so that a difference in a total perimeter of respective diffusion regions of all transistors belonging to the standard cell between the standard cell and each of other standard cells becomes small.

In one embodiment of the standard cell design method of the present invention, the method is characterized in that respective scales of the standard cell and other standard cells are different, the substrate contact is expanded according to the ratio between the scales of the standard cell and each of the other standard cells.

A semiconductor integrated circuit according to the present invention is characterized by including a plurality of standard cells designed according to any one of the above-described standard cell design methods.

A semiconductor integrated circuit according to the present invention is a semiconductor integrated circuit fabricated so as to have a structure in which at least three standard cells each including a dummy transistor at each end portion are arranged and is characterized in that a gate electrode length of the dummy transistor disposed between one of the three standard cells located in the center and another of the three standard cells located on the left is different from a gate electrode length of the dummy transistor disposed between the standard cell located in the center and another of the three standard cells located on the right according to a difference in a total surface area or a total perimeter of respective gate electrodes of transistors between the center standard cell and the left standard cell and a difference in a total surface area or a total perimeter of respective gate electrodes of transistors between the center standard cell and the right standard cell.

As has been described, according to the present invention, in each standard cell, the surface area, gate length or perimeter of a gate electrode of each of dummy transistors belonging to a standard cell and the area of each of substrate contacts belonging to the standard cell are adjusted, so that among standard cells, a difference in the total surface area or total perimeter of respective gate electrodes of all transistors belonging to a standard cell, or a difference in the total area or total perimeter of respective diffusion regions of all transistors belonging to a standard cell becomes small. Thus, for example, in light exposure and transcription, even if there are differences in device shapes of gate electrodes and diffusion regions among cells due to influences of diffracted light of the light exposure and transcription and the like, variations in delay of a signal due to the layout pattern dependency among cells can be more effectively suppressed than in the known technique.

### BRIEF DESCRIPTION OF THE DRAWINGS

FIG. 1 is a view illustrating a layout structure of a standard cell according to Embodiment 1 of the present invention.

FIG. 2 is a view three-dimensionally illustrating a gate electrode of a transistor.

FIG. 3A is a view illustrating a modified example of dummy transistor parts disposed at the left and right of the standard cell and FIG. 3B is a view illustrating another modified example of the dummy transistor parts.

FIG. 4 is a view illustrating gate electrode parts taken out of the layout structure of a standard cell according to Embodiment 2 of the present invention.

FIG. 5 is a view illustrating a semiconductor integrated circuit according to Embodiment 3 of the present invention.

FIG. 6 is a view illustrating a basic layout structure of a known standard cell.

FIG. 7 is a view illustrating a layout structure of a standard cell according to Embodiment 4 of the present invention.

FIG. 8 is a view illustrating a diffusion region taken out of the layout structure of a standard cell according to Embodiment 5 of the present invention.

FIG. 9 is a view illustrating the structure of a semiconductor integrated circuit device according to Embodiment 6 of the present invention.

FIG. 10 is a scanning electron microscope photo showing how gate electrodes and diffusion regions of transistors in a standard cell are scraped at various parts when being formed.

### DESCRIPTION OF THE PREFERRED EMBODIMENTS

Hereinafter, embodiments of the present invention will be described with reference to the accompanying drawings.

### Embodiment 1

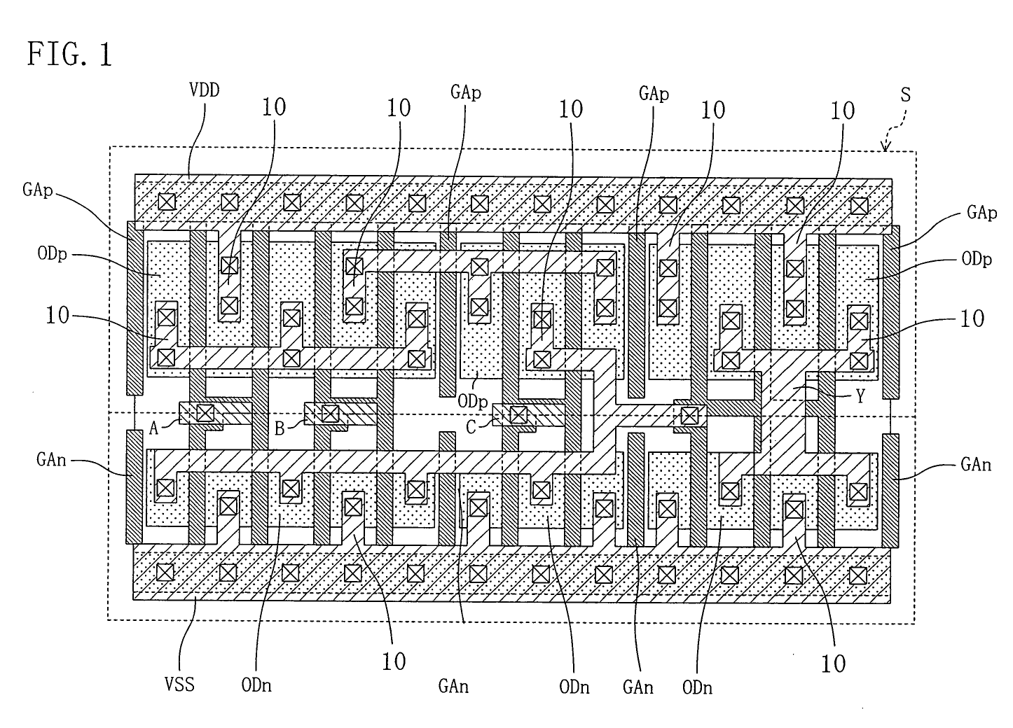

FIG. 1 is a view illustrating a layout structure of a standard cell according to an embodiment of the present invention. In a standard cell S of FIG. 1, VDD denotes a power source line, VSS denotes a ground line, 10 denotes a gate electrode, and ODp and ODn denotes diffusion regions. A plurality of polysilicon gate electrodes 10 (24 gate electrodes in FIG. 1) are arranged above diffusion regions ODp and ODn, so that 12 p-type and n-type MOSFET transistors (which will be hereafter referred to as “active transistors”) to be normally used are formed.

Furthermore, in the standard cell S, GAp and GAn are of a polysilicon gate electrode connected to a source supply line VDD or a ground line VSS. Each of the polysilicon gate electrodes is located at a side of an associated one of the diffusion regions ODp and ODn and does not intersect with the associated one of the diffusion regions ODp and ODn. Thus, each of the gate electrodes GAp and GAn forms part of a p-type or n-type MOSFET dummy transistor which is in an OFF state at all the time. As respective gate electrodes GAp and GAn of the p-type and n-type dummy transistors (which will be hereafter referred to as “dummy gate electrodes”), eight gate electrodes in total are provided. Specifically, two dummy gate electrodes are provided in each of right and left side portions of the cell S and four dummy gate electrodes are provided inside of the cell S.

In the p-type and n-type gate electrodes 10, GAp and GAn, an interval between adjacent ones of the plurality of gate electrodes 10 is set to be a predetermined distance and also an interval between each of the gate electrodes 10 and adjacent one of the dummy gate electrodes GAp and GAn is also set to be the predetermined distance. Note that in FIG. 1, A, B and C denote signal input terminals for connecting the cell S to the outside, and Y denotes a signal output terminal.

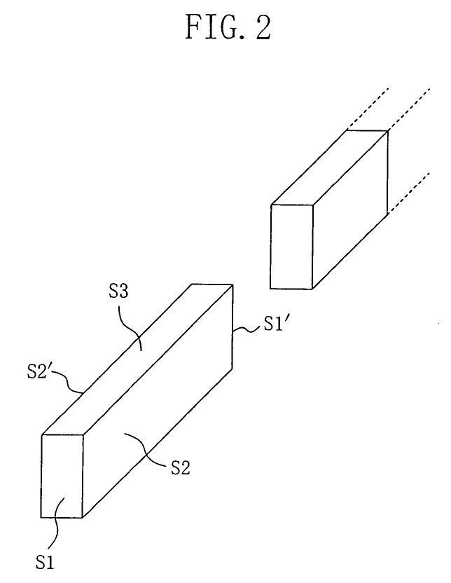

In chemical vapor deposition (CVD), if the amount of supplied gas is constant, the oxide film thickness of each gate electrode depends on the surface area of the gate electrode. FIG. 2 is a view three-dimensionally illustrating the surface area of the gate electrode 10 and the dummy gate electrodes GAp and GAn. If the surface area of the gate electrode of FIG. 2 is assumed to be Sa, the surface area Sa can be expressed by the following Equation 1.
Sa=S1+S1′+S2+S2′+S3
(S1=S1′, S2=S2′) [Equation 1]

The oxide film of the gate electrode is grown predominantly in proportion to the surface area Sa. Accordingly, if the surface area Sa of the gate electrode varies depending on the type of the cell, the oxide film thickness of the gate electrode is changed depending on the type of the cell, so that a value of an effective gate electrode length varies. Therefore, variations in transistor characteristics due to layout pattern dependency occur.

According to this embodiment, to eliminate layout pattern dependency, an adjustment is performed so that among the standard cells of different types, a difference in the total of the surface areas Sa of respective gate electrodes of transistors belonging to a standard cell, and, specifically, the total of the side surface areas S2 of the gate electrodes becomes small. In this embodiment, as shown in FIG. 1, the dummy gate electrodes GAp and GAn of the p-type and n-type dummy transistors are disposed so that each of the dummy gate electrodes GAp is opposed to an associated one of the dummy gate electrodes GAn with a predetermined distance therebetween and each of the dummy gate electrodes GAp and GAn is lengthened with the widths and heights of the dummy gate electrodes GAp and GAn fixed so that respective ends of each pair of the dummy gate electrodes GAn and GAp become closer to each other.

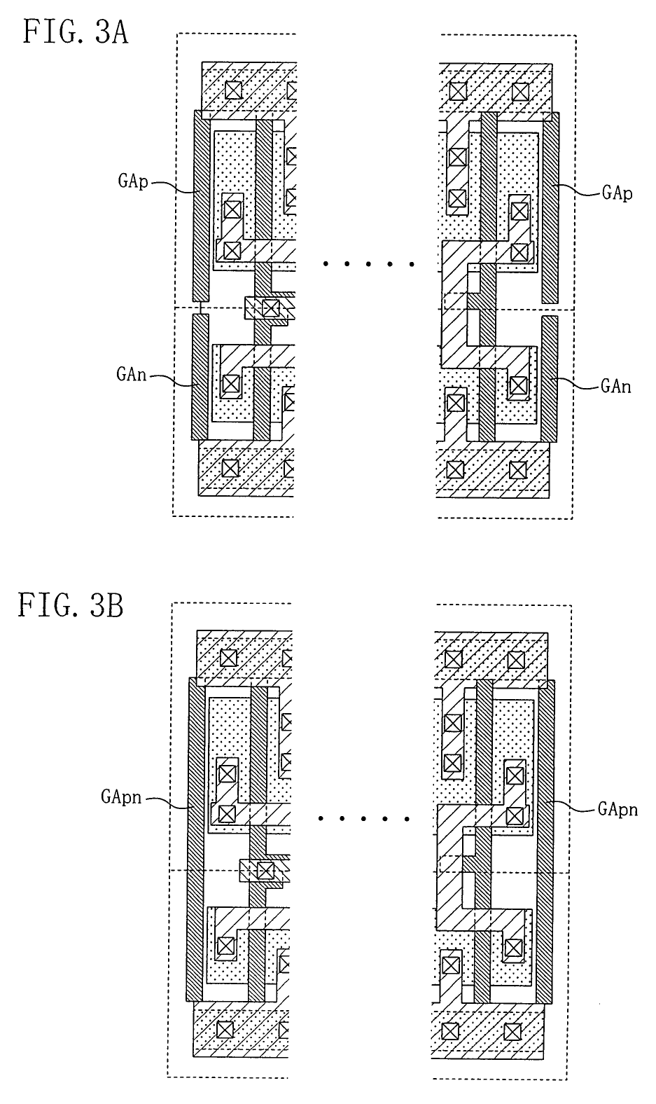

FIGS. 3A and 3B are views illustrating modified examples of the dummy gate electrodes GAp and GAn located at left and right ends of the standard cell S of FIG. 1. In FIG. 3A, the length of each of the dummy gate electrodes Gap and GAn opposed to each other is increased furthermore. In FIG. 3B, the length of each of the dummy gate electrodes Gap and GAn opposed to each other is increased furthermore so that the dummy gate electrodes GAp and GAn are connected to each other, thereby forming a dummy gate electrode GApn.

When between two different types of standard cells, the respective scales of the cells are largely different, an adjustment may be performed so that a difference in the ratio of the total surface area of dummy gate electrodes to the surface area of a cell between the cells is small or various other comparison references may be provided.

### Embodiment 2

Next, Embodiment 2 of the present invention will be described.

In Embodiment 1, the surface area of each of the dummy gate electrodes GAp and GAn are adjusted to reduce influences on transistor characteristics due to the layout dependency. In contrast, according to this embodiment, to reduce the layout pattern dependency, a perimeter of each of the dummy gate electrodes GAp and GAn is adjusted thereby reducing influences on transistor characteristics.

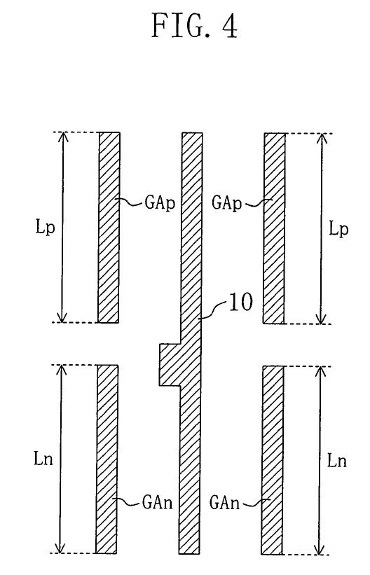

FIG. 4 is a view illustrating gate electrode part taken out of the layout structure of a standard cell S. The total perimeter of respective gate electrodes of all transistors belonging to a cell differs depending to the type of the cell. Then, in FIG. 4, the respective lengths Lp and Ln of dummy gate electrodes GAp and GAn are adjusted to reduce a difference in the total perimeter of respective gate electrodes of all transistors of the cell among cells of different types, thereby reducing influences on transistor characteristics.

Herein, the dummy gate electrodes GAp and GAn are not limited to dummy gate electrodes located at end boundaries of the cell S, but dummy gate electrodes located in the cell S may be used.

If the scales of the cells are largely different between two different types of standard cells, an adjustment may be performed so that a difference in the ratio of the total perimeter of dummy gate electrodes to the surface area of a cell between the cells becomes small. Alternatively, various other comparison references may be provided.

### Embodiment 3

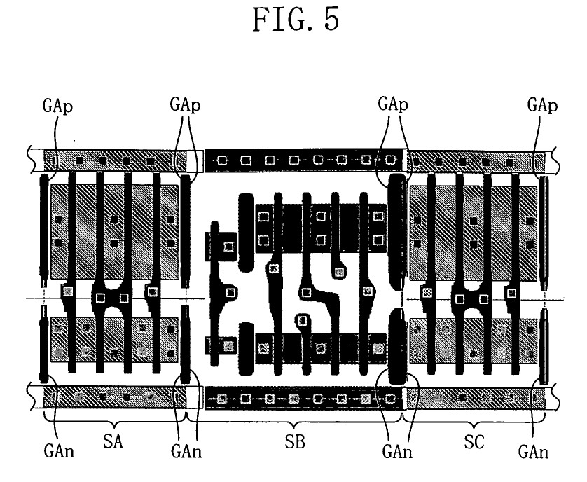

Subsequently, Embodiment 3 of the present invention will be described with reference to FIG. 5. In this embodiment, a predetermined semiconductor integrated circuit is formed using a plurality of standard cells according to the present invention.

In FIG. 5, three standard cells SA, SB, and SC are used. For the cells SA, SB, and SC, cells of Embodiment 1 or Embodiment 2 in which the surface area and perimeter of dummy gate electrodes are adjusted are used. In FIG. 5, the cells SA and SC located on the left and the right, respectively, are the same type of cells and the cell SB located in the center is a cell of a different type. In each of the cells, as has been described, the dummy gate electrodes GAp and GAn are provided at left and right end sections. The lengths of the dummy gate electrodes GAp and GAn are adjusted so that a difference between the cell SA and the cell SB and a difference between the cell SC and the cell SB in the total surface area or total perimeter of respective gate electrodes of transistors belonging to the cell are reduced.

When the cell SC located at the right end in FIG. 5 is a cell of a different type, the lengths of the dummy gate electrodes GAp and GAn are adjusted so that a difference between the center cell SB and the right cell SC in the total surface area or total perimeter of gate electrodes of transistors belonging to the cell becomes small. In such a case, the gate lengths of the dummy gate electrodes GAp and GAn located between the cell SA at the left end and the cell SB at the center are different from the lengths of the dummy gate electrodes GAp and GAn located between the cell SB at the center and the cell SC at the right end.

### Embodiment 4

Subsequently, Embodiment 4 of the present invention will be described.

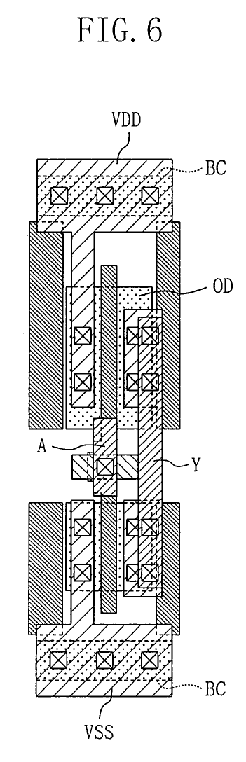

First, a basic layout structure of a standard cell will be described in FIG. 6. In FIG. 6, VDD denotes a power supply region, VSS denotes a ground region, OD denotes a diffusion region, and BC denotes a substrate contact section, i.e., a diffusion region.

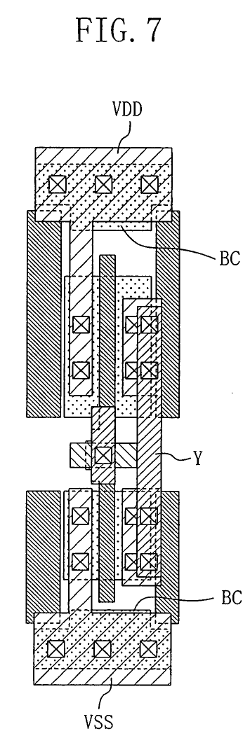

FIG. 7 is a view illustrating a layout structure of a standard cell according to this embodiment. In FIG. 7, to reduce a difference in the total area of diffusion regions in a cell among different cells, the substrate contact section BC is expanded toward the inside of the cell and the area of a substrate contact section BC is increased in the layout structure of the standard cell of FIG. 6.

Depending on the type of a cell, the total area of diffusion regions in a cell differs and thus variations in transistor characteristics due to the layout pattern dependency occur.

To reduce the layout pattern dependency according to the area of the diffusion region OD, in this embodiment, as has been described, the substrate contact section BC is expanded toward the inside of the cell, so that a difference in the total area of diffusion regions in the cell between different cells is reduced. Thus, influences on transistor characteristics can be reduced. In expansion of the substrate contact section BC toward the inside of a cell, the substrate contact section BC is expanded within a range which satisfies design constraints.

The larger the total area of diffusion regions is, the larger the height of STIs (shallow trench isolations) becomes, so that an electric field is hardly applied to each gate electrode. If a high electric filed is applied to a gate electrode, a tunnel current flows in an oxide film of the gate electrode, so that breakdown and deterioration of the oxide film of the gate electrode are caused. Such deterioration directly results in defects of a transistor or reduction in fabrication yield of a transistor. Therefore, it is effective in improving performances of a transistor to expand the substrate contact section toward the inside of a cell to increase the total area of diffusion regions in the cell.

### Embodiment 5

Next, Embodiment 5 of the present invention will be described.

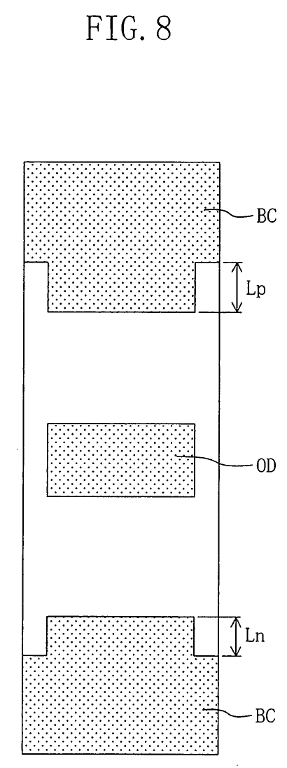

FIG. 8 is a view illustrating a layout structure of a diffusion region taken out of a standard cell of Embodiment 5.

In general, a perimeter of a diffusion region differs depending on the type of a cell. A total perimeter of total diffusion regions is defined to be the total of respective perimeters of all of diffusion regions in a cell. In FIG. 8, among respective perimeters of diffusion regions, the lengths Lp and Ln of parts of two substrate contacts BC which are to be expanded toward the inside of the cell are controlled to reduce a difference in the total perimeter of diffusion regions between different cells, thereby reducing influences on transistor characteristics.

If the scales of the cells are largely different between two different types of standard cells, various comparison references such as the ratio of the total perimeter of diffusion regions to the perimeter of a cell, the ratio of the total perimeter of diffusion regions to the surface area of a cell and the like may be made between the different cells.

### Embodiment 6

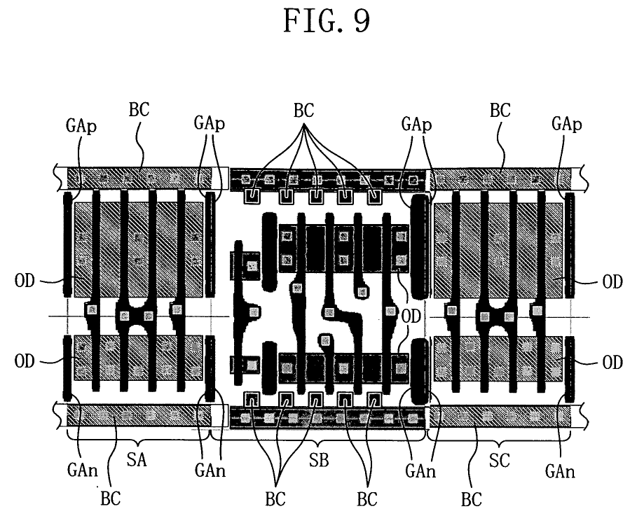

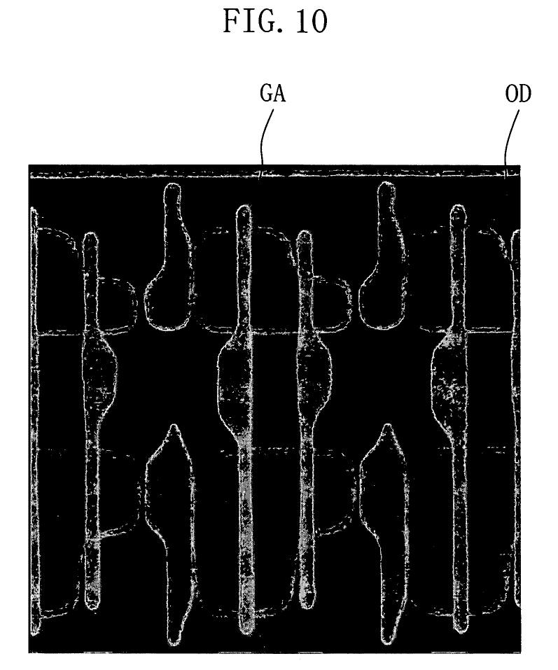

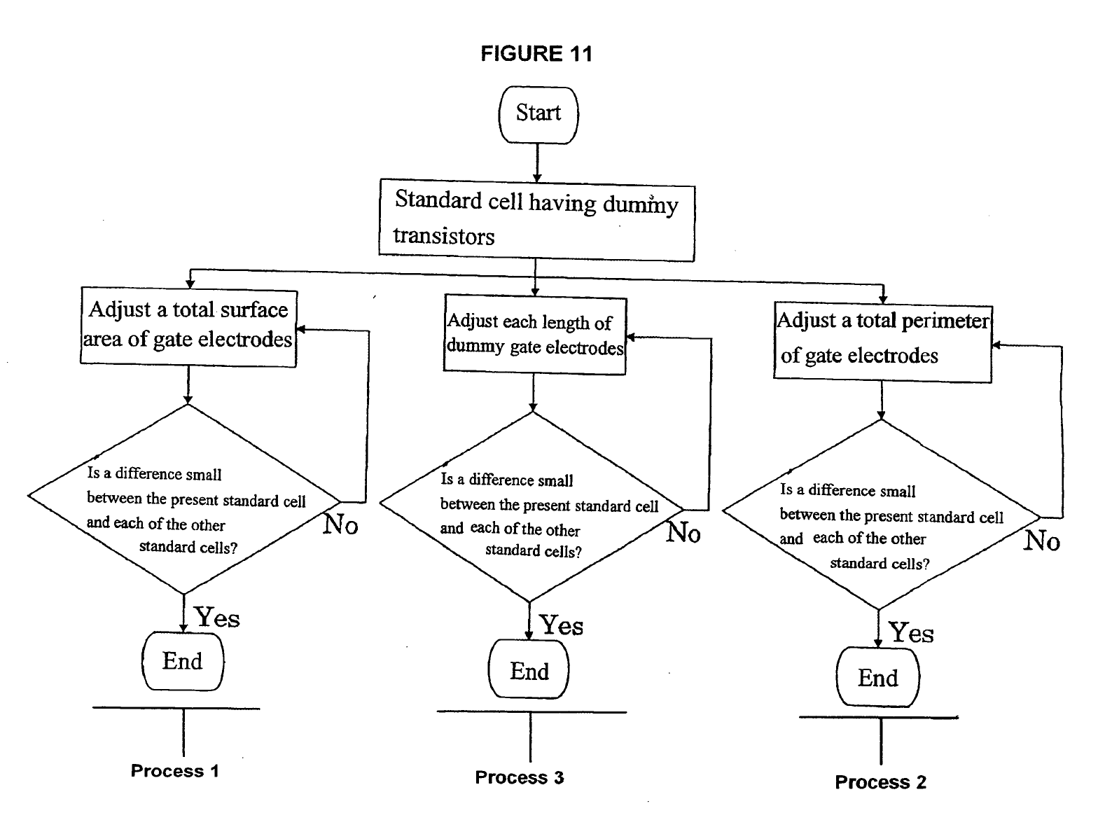

Subsequently, Embodiment 6 of the present invention will be described with reference to FIG. 9. In this embodiment, a predetermined semiconductor integrated circuit is formed using a plurality of standard cells according to the present invention.

In FIG. 9, three standard cells SA, SB and SC are used. The cell SB located in the center is a cell with substrate contacts whose area is adjusted in the manner described in Embodiment 4 or Embodiment 5. In FIG. 9, the cells SA and SC located in the left and the right, respectively, are cells of the same type and the cell SB is a cell of a different type.

In each cell, diffusion regions OD on which gate electrodes of active transistors are to be disposed are formed. In the cell SB located in the center, the total area of the diffusion regions OD is small, compared to diffusion regions of the cells SA and SC located on the left and the right, respectively. Accordingly, as shown in FIG. 9, substrate contacts BC of the center cell SB are inwardly expanded and the total area of the substrate contacts BC is increased, so that a difference in the total area of diffusion regions between the diffusion regions of the center cell SB and each of the left and right SA and SC is reduced.

Therefore, in this embodiment, a difference in the total area of diffusion regions among the cells SA, SB and SC is small. Thus, the layout pattern dependency due to the total area of diffusion regions is substantially equal among the cells SA, SB and SC, so that transistor characteristics of each of the cells become equal. As a result, a high performance semiconductor integrated circuit with small fluctuation in characteristics can be achieved.

In FIG. 9, as has been described, the dummy gate electrodes Gap and GAn are disposed at left and right end portions, respectively in each of the cells SA, SB and SC.

1-11. (canceled)

12. A semiconductor integrated circuit having a structure in which at least right, center, and left standard cells are arranged,
wherein a length of a first dummy gate electrode disposed between the center and left standard cells and a length of a second dummy gate electrode disposed between the center and right standard cells differ from each other according to a difference in a total surface area of gate electrodes of transistors between the center and left standard cells and a difference in a total surface area of gate electrodes of transistors between the center and right standard cells.

13. The semiconductor integrated circuit of claim 12, wherein the first or second dummy gate electrode which has a shorter length is arranged adjacent to one of the right, center and left standard cells which has a greatest total surface area of gate electrodes of transistors.

14. The semiconductor integrated circuit of claim 12, wherein each of the first and second dummy gate electrodes constitutes part of one of the right, center and left standard cells.

15. The semiconductor integrated circuit of claim 13, wherein each of the first and second dummy gate electrodes constitutes part of one of the right, center and left standard cells.

16. A semiconductor integrated circuit having a structure in which at least right, center, and left standard cells are arranged,
wherein a length of a first dummy gate electrode disposed between the center and left standard cells and a length of a second dummy gate electrode disposed between the center and right standard cells differ from each other according to a difference in a total perimeter of gate electrodes of transistors between the center and left standard cells and a difference in a total perimeter of gate electrodes of transistors between the center and right standard cells.

17. The semiconductor integrated circuit of claim 16, wherein the first or second dummy gate electrode which has a shorter length is arranged adjacent to one of the right, center and left standard cells which has a greatest total perimeter of gate electrodes of transistors.

18. The semiconductor integrated circuit of claim 16, wherein each of the first and second dummy gate electrodes constitutes part of one of the right, center and left standard cells.

19. The semiconductor integrated circuit of claim 17, wherein each of the first and second dummy gate electrodes constitutes part of one of the right, center and left standard cells.

20. A semiconductor integrated circuit having a structure in which at least right, center, and left standard cells are arranged,
wherein a gate length of a first dummy gate electrode disposed between the center and left standard cells and a gate length of a second dummy gate electrode disposed between the center and right standard cells differ from each other according to a difference in a total surface area of gate electrodes of transistors between the center and left standard cells and a difference in a total surface area of gate electrodes of transistors between the center and right standard cells.

21. The semiconductor integrated circuit of claim 20, wherein the first or second dummy gate electrode which has a smaller gate length is arranged adjacent to one of the right, center and left standard cells which has a greatest total surface area of gate electrodes of transistors.

22. The semiconductor integrated circuit of claim 20, wherein each of the first and second dummy gate electrodes constitutes part of one of the right, center and left standard cells.

23. The semiconductor integrated circuit of claim 21, wherein each of the first and second dummy gate electrodes constitutes part of one of the right, center and left standard cells.

24. A semiconductor integrated circuit having a structure in which at least right, center, and left standard cells are arranged,
wherein a gate length of a first dummy gate electrode disposed between the center and left standard cells and a gate length of a second dummy gate electrode disposed between the center and right standard cells differ from each other according to a difference in a total perimeter of gate electrodes of transistors between the center and left standard cells and a difference in a total perimeter of gate electrodes of transistors between the center and right standard cells.

25. The semiconductor integrated circuit of claim 24, wherein the first or second dummy gate electrode which has a smaller gate length is arranged adjacent to one of the right, center and left standard cells which has a greatest total perimeter of gate electrodes of transistors.

26. The semiconductor integrated circuit of claim 24, wherein each of the first and second dummy gate electrodes constitutes part of one of the right, center and left standard cells.

27. The semiconductor integrated circuit of claim 25, wherein each of the first and second dummy gate electrodes constitutes part of one of the right, center and left standard cells.
